(19) United States
(12) Patent Application Publication
(10) Pub. No.: US 2003/0155572 A1
(43) Pub. Date: Aug. 21, 2003

(54) Thin film transistor and method for manufacturing thereof

(76) Inventors: Min-Koo Han, Seoul (KR); Cheon-Hong Kim, Seoul (KR); In-Hyuk Song, Pusan-Kwangyokshi (KR)

Correspondence Address: Michael A. Cantor, 55 Griffin South Road, Bloomfield, CT, 06002, US

(21) Appl. No.: 10/166,466

(22) Filed: Jun. 10, 2002

(30) Foreign Application Priority Data
Feb. 19, 2002 (KR) 8777/2002

(51) Int. Cl. H01L 29/76; H01L 31/036; H01L 31/112; H01L 27/01; H01L 27/12; H01L 31/0392

(52) U.S. Cl. 257/66; 257/347

(57) ABSTRACT

The disclosure is concerned in a thin-film transistor and method of fabricating thereof, forming a heat blocking layer under a channel region of a semiconductor layer. The heat blocking layer, having a lower thermal conductivity, reduces a heat transmission rate along a vertical direction. The channel region is crystallized into a structure of coarse grains through lateral heat transmission.

### PRIORITY

This application claims priority to an application entitled “THIN FILM TRANSISTOR AND METHOD FOR MANUFACTURING THEREOF” filed in the Korean Industrial Property Office on Feb. 19, 2002 and assigned Serial No. 2002-8777, the contents of which are hereby incorporated by reference.

### BACKGROUND OF THE INVENTION

1. Field of the Invention

The present invention relates generally to thin film transistors and method of fabricating thereof, and in particular, to thin film transistors formed of polycrystalline grains with uniform coarseness more than 0.4 μm and method of fabricating thereof.

2. Description of the Related Art

Active-matrix liquid-crystal-display (AM-LCD) panels employing low-temperature polycrystalline silicon thin-film transistors (poly-Si TFTs) are increasingly adoptable to high-resolution LCD display apparatuses, because they are more facilitative in achieving higher current drivability and integration density rather than those with amorphous silicon thin-film transistors (a-Si TFTs). It has been known that an eximer laser annealing on amorphous silicon may result in polycrystalline silicon thin films with lower defect density. But, considering that field-effect mobility and current drivability are very involved in grain sizes, the polycrystalline Silicon films obtained from the excimer laser annealing process are not proper for TFTs of drive circuits of LCD display apparatuses because their grains size smaller than 0.5 μm usually.

So, there have been proposed various studies for enlarging the grain sizes, recently such as a technique of employing the sequential lateral solidification (SLS) and the optical phase shift mask. However, the former way to enlarge the grain sizes needs an apparatus for precisely aligning substrate positions and must conduct many times of laser irradiation, which causes complexity of process and difficulty of obtaining reliable film properties.

### SUMMARY OF THE INVENTION

It is, therefore, an object of the present invention to provide a thin-film transistor formed of polycrystalline silicon grains with uniform coarseness more than 4 μm and method for fabricating thereof.

It is another object of the present invention to provide a thin-film transistor and method thereof, capable of obtaining reliable grain structure with uniformity by means of one-timed laser irradiation.

To achieve the above and other objects, there is provided a thin-film transistor comprising: an insulated substrate; a heat blocking layer, definitively formed on the insulated substrate, for reducing a heat transmission rate along a vertical direction, having a lower thermal conductivity; a semiconductor layer covering the heat blocking layer, including a source region, a drain region, and a channel region defined on the heat blocking layer; an insulating layer formed on the semiconductor layer, being defined on the channel region; and a gate electrode formed on the insulating layer, overlapping the channel region.

The heat blocking layer is formed of the air. The semiconductor layer at the channel region is formed of lateral-grown polycrystalline silicon grains larger than 4 μm.

A method of fabricating a thin-film transistor comprises the steps of: preparing an insulated substrate; forming a passivation pattern on a predetermined area of the insulated substrate, the passivation pattern creating a step coverage over the predetermined area; sequentially depositing an insulating layer, an amorphous silicon layer, and a capping layer and selectively etching the capping layer, the amorphous silicon layer, and the insulating layer to form an active pattern; removing the passivation pattern; converting the amorphous silicon defined in the channel region into a polycrystalline silicon layer by means of an annealing process; removing the capping layer; forming a gate insulation layer and a gate electrode on the polycrystalline silicon layer; and implanting ions into the source and drain regions with a mask composed of the gate insulation layer and the gate electrode and carrying out an annealing process.

The passivation pattern is made of a material selectively removable by a wet etching process.

According to another aspect of the invention, a method of fabricating a thin-film transistor comprises the steps of: preparing an insulated substrate; forming a heat blocking layer defined on a predetermined area of the insulated substrate, the heat blocking layer reducing a heat transmission rate along a vertical direction and having a lower thermal conductivity; sequentially depositing an insulating layer, an amorphous silicon layer, and a capping layer and selectively etching the capping layer, the amorphous silicon layer, and the insulating layer to form an active pattern; converting the amorphous silicon defined in the channel region into a polycrystalline silicon layer by means of an annealing process; removing the capping layer; forming a gate insulation layer and a gate electrode on the polycrystalline silicon layer; and implanting ions into the source and drain regions with a mask composed of the gate insulation layer and the gate electrode and carrying out an annealing process.

### BRIEF DESCRIPTION OF THE DRAWINGS

The above and other objects, features and advantages of the present invention will become more apparent from the following detailed description when taken in conjunction with the accompanying drawings in which:

FIG. 1 is a sectional diagram illustrating a structure of a thin-film transistor according to the present invention;

FIG. 2 is a photographic diagram, by means of a scanning electron microscope (SEM), showing a pattern of polycrystalline silicon grains grown in a thin-film transistor according to the invention;

FIGS. 3A and 3B are photographic diagram, by means of a SEM, showing the sizes of the polycrystalline silicon grains taken along with energy spectrum density;

FIG. 4 is a graphic diagram plotting the sizes of lateral growth along energy density;

FIGS. 5A and 5D are sectional diagrams showing sequential processing steps for fabricating the thin-film transistor according to an embodiment of the invention;

FIG. 6 is a graphic diagram plotting current-voltage transmission characteristics and field-effect mobility of the thin-film transistor fabricated by an embodiment of the invention;

FIG. 7 is a graphic diagram plotting characteristics of the present thin-film transistor in accordance with laser energy density; and

FIG. 8 is a graphic diagram showing electrical stability of the present thin-film transistor in accordance with structures of grains.

### DETAILED DESCRIPTION OF THE PREFERRED EMBODIMENT

A preferred embodiment of the present invention will be described herein below with reference to the accompanying drawings. In the following description, well-known functions or constructions are not described in detail since they would obscure the invention in unnecessary detail.

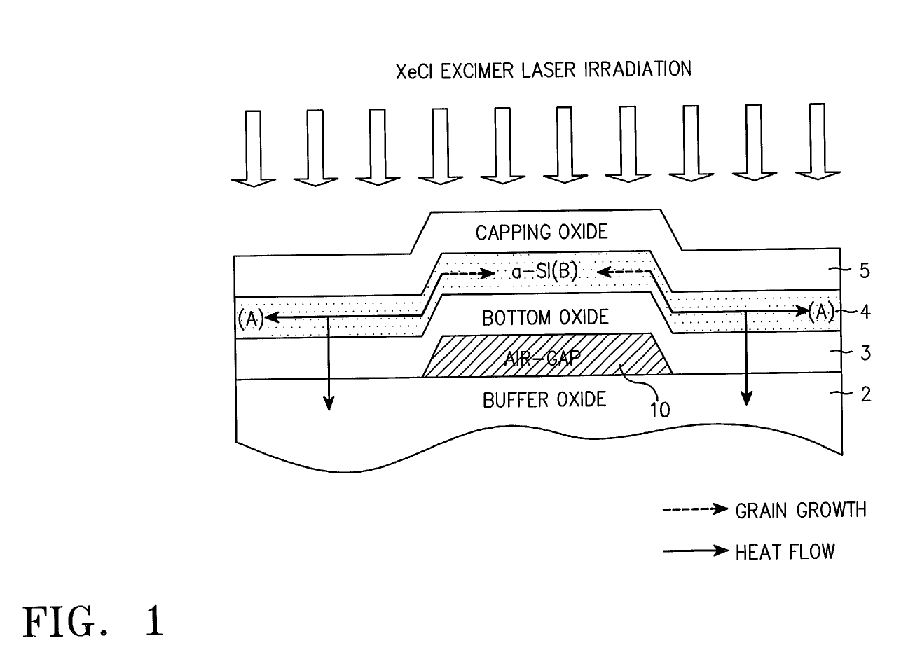

FIG. 1 shows a vertical structure of a thin-film transistor according to the present invention. Referring to FIG. 1, the thin-film transistor is formed of a buffer oxide layer 2, a bottom oxide layer 3, an amorphous silicon layer 4 of amorphous silicon including a drain region 6, a source region 7, and a channel region 8, and a capping oxide layer 5. The channel 8 is interposed between the drain region 6 and the source region 7, being conductive selectively in operation. Between the buffer oxide layer 2 and the bottom oxide layer 3 is partially interposed an air gap 10 under the channel region 8. The air gap 10 is provided to reduce heat transmission along a vertical direction. It is available for the air gap 10 to use a proper material having low conductivity for heat. When an eximer laser (e.g., of XeCl) is being irradiated on the structure for annealing, the channel region 8 is less influenced from a vertical transmission of heat, due to a presence of the air gap 10 having low heat conductivity. On the other hand, as at the drain and source regions, 6 and 7, the amorphous silicon film contacts with the substrate the bottom oxide layer 3, the heat in the amorphous silicon layer 4 is transferred into the lower oxide layer. Such a heat transmission causes a difference of heat distribution between the drain and source regions, 6 and 7, and the channel region 8, resulting in a discharge of heat from the channel region 8 to the drain and source regions. Thus, the solicidation at the channel region 8 proceeds towards the center of the channel region 8 from the boundaries between the channel region and the drain and source regions. The boundaries between the channel region and the drain and source regions act as solicidation seeds for poly-crystallization to form lateral-growing coarse grains.

The capping oxide layer 5 on the amorphous silicon layer 4 prevents the active layers of the amorphous silicon layer 4 from distortion of pattern due to evaporation thereof during the laser irradiation. Without the capping layer 5, the active layer, i.e., the channel region 8, may be partially evaporated out because it contains heat during activation and is not associative with vertical discharge means against heat.

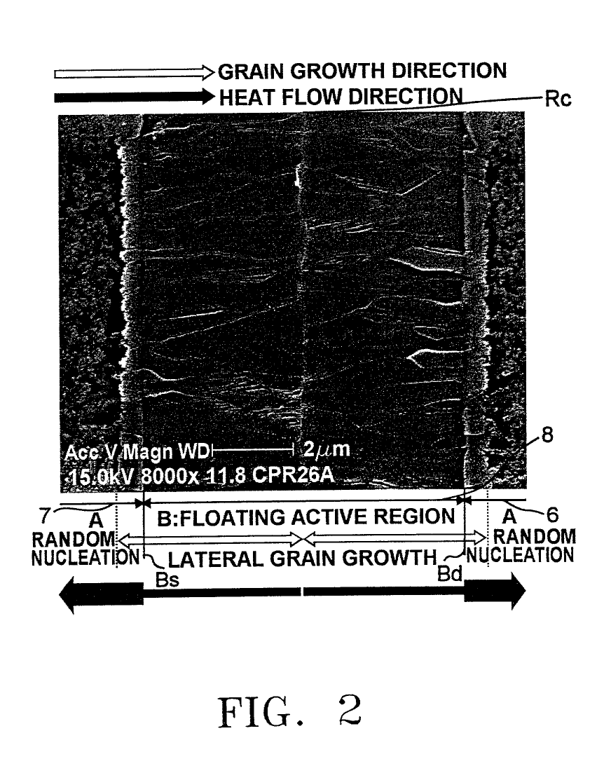

Referring to FIG. 2 showing a pattern of polycrystalline silicon grains grown in a thin-film transistor, taken by a scanning electron microscope (SEM), it can be seen that the grains start to first grow with the lateral directions from the boundaries Bd (between the drain region 6 and the channel region 8) and Bd (between the source region 7 and channel region 8) towards the center the channel region 8. The growth of the grains terminates at the center region Rc of the channel region 8, the growing flows from the boundaries Bd and Bs stopping to proceed at the center region Rc.

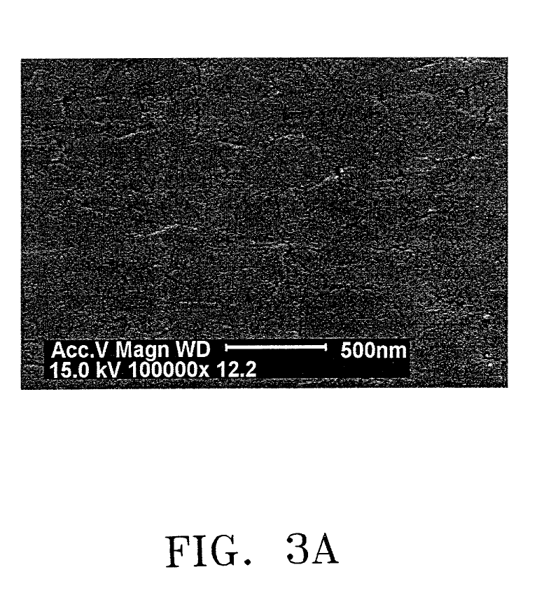

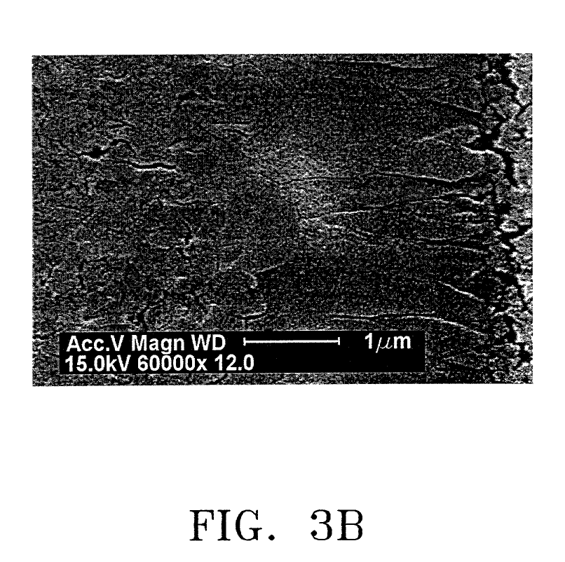

Meanwhile, the grain sizes are variable in accordance with energy density of laser, as shown in FIGS. 3A and 3B that obtains by means of a scanning electron microscope (SEM) in the conditions of energy densities of 200 mJ/cm² and 250 mJ/cm², respectively. Referring to FIG. 3B, the energy density lower than 200 mJ/cm² is not sufficient to generate the grain growth because the amorphous silicon film partially melts and the lateral propagation of heat does not occur, resulting in formation of small-sized grains as a whole. However, referring to FIG. 3B, if the energy density is over 250 mJ/cm², the lateral propagation of heat occurs to cause the lateral growth of the grains. While this, it is difficult to complete the lateral grain growth to fully fill out the active layer of the channel region 8, which results from the fact that homogeneous nucleation induces small grains to obstruct the lateral extension of the grains growing from the boundaries.

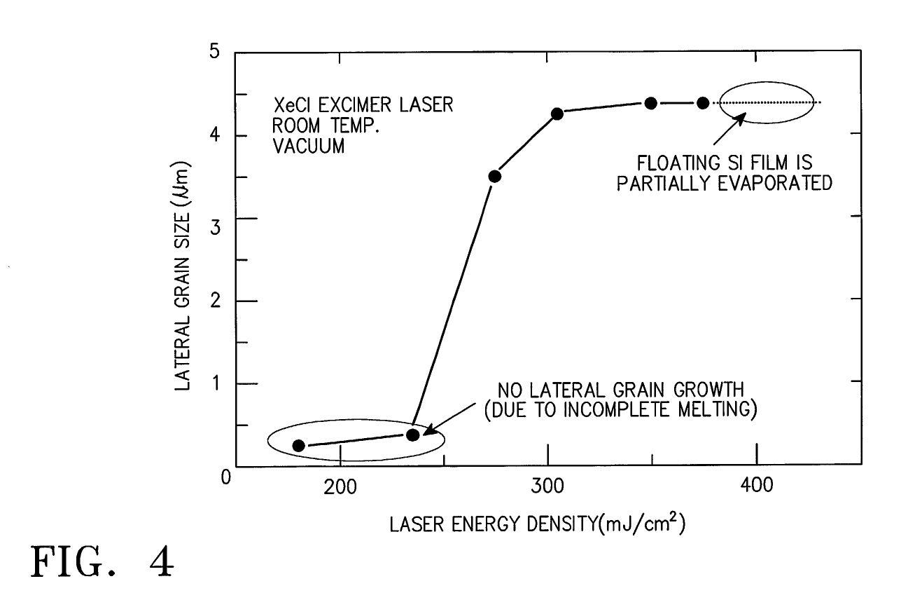

The graph of FIG. 4 shows that the grains has been successfully grown in the energy density approximately between 280 mJ/cm² and 400 mJ/cm² while occurring a partial evaporation of the active film in the energy density over 400 mJ/cm².

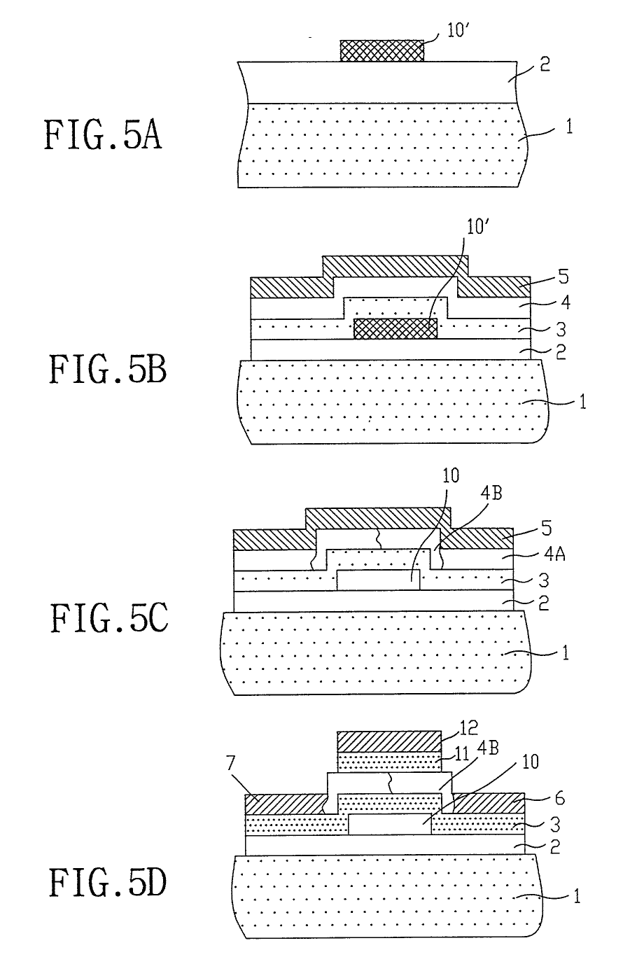

Form now on, it explains a procedure for fabricating the thin film transistor, as shown in FIG. 1, according to the present invention with reference to FIGS. 5A through 5D.

First, in FIG. 5A, the buffer oxide layer 2 is deposited on a wafer 1 made of crystal or glass. A molybdium (Mo) layer in use for passivation is deposited on the buffer oxide layer 2 and then is formed into a pattern 10′ defined within the scope of the channel region 8 by means of a photolithography process. The molybdium may be substituted with other metals, adoptable to retaining thermal and mechanical stabilities, such as Cl or Cr.

After, in FIG. 5B, the bottom oxide layer 3 of 100 nm, the amorphous silicon layer 4 of 80 nm, and the capping oxide layer 5 of 50 nm, in this order, are sequentially stacked on the structure of FIG. 5A by means of a plasma-enhanced chemical-vapor deposition (PECVD). As stated above, the capping layer 5 contributes to protect the pattern of the active layer (i.e., the channel region 8) from evaporation during a laser irradiation for annealing. The layers 5, 4, and 3 are patterned to define the active area, exposing the sides of the molybdium pattern 10′.

Next, as shown in FIG. 5C, the molybdium pattern 10′ as a passivation layer for is eliminated by means of a wet etching process with an etchant of 16H₃PO₄: 1HNO₃: 1HAC: 2H₂O in 50° C. The etchant may be variable with its compound ratio in accordance with a kind of the passivation pattern (i.e., 10′) and eliminates it selectively. For instance, while the etchant aforementioned is adaptable to a passivation pattern formed of aluminum (Al) even instead of molybdium, chromium (Cr) as the passivation pattern is selectively eliminable by the specific etchant Cr-7.

The vacant space after removing the molybdium pattern 10′ turns to the air gap 10 filling with the air, supporting the channel region 8 of the amorphous silicon layer 10 with a step coverage thereat.

Subsequently, referring to FIG. 5C, crystallization for the amorphous silicon layer 4 is carried out by means of the eximer laser irradiation, so that the amorphous silicon layer 4 is converted into a layer 4B formed of larger lateral grains that are grown with the desirable shape shown in FIG. 3B.

Finally, as shown in FIG. 5D, after removing the capping oxide layer 5, a Tetra-ethyl-ortho-silicate (TEOS) layer 11 and an aluminum layer 12 are sequentially deposited thereon and then patterned respectively into the gate oxide layer and the gate electrode. Using the gate electrode 12 and the gate oxide layer 11 as a mask pattern, an ion implantation process is carried out with phosphorous ions in dose concentration of 5×10¹⁵ ions/cm² under 30 KeV. And, a laser beam is irradiated thereto in order to activate the implanted ions, completing the source and drain regions, 6 and 7.

After then, although not shown in the Figures, it proceeds the following processing steps of depositing an oxide layer, forming contact holes to connect the source and drains regions to external circuits, forming metal connections, and depositing a passivation layer, in this order, thereby resulting in the structure of the polycrystalline silicon thin-film transistor.

In the fabricating procedure, the highest temperature is established at 450° C. in the environment of PE-CVD, which is a low-temperature process applicable to a TFT-LCD formed on a glass.

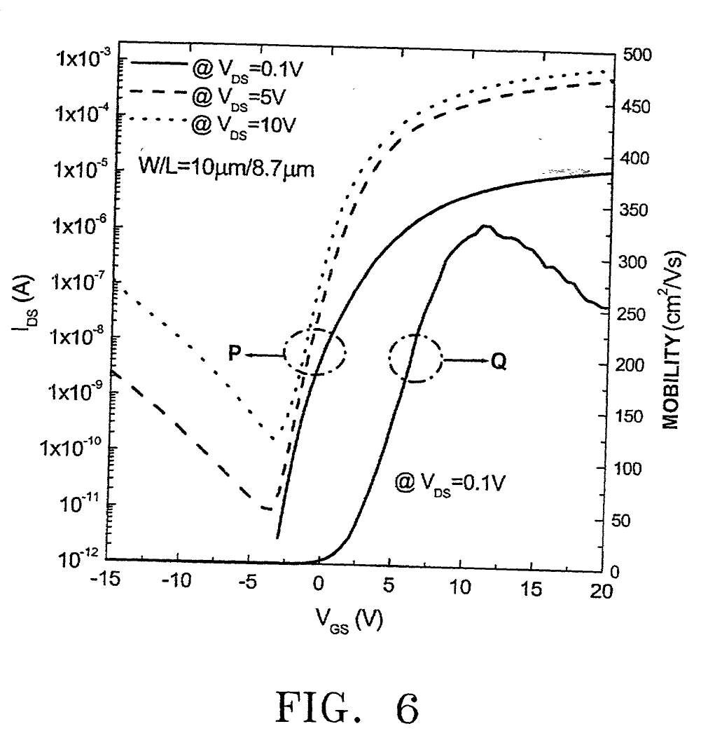

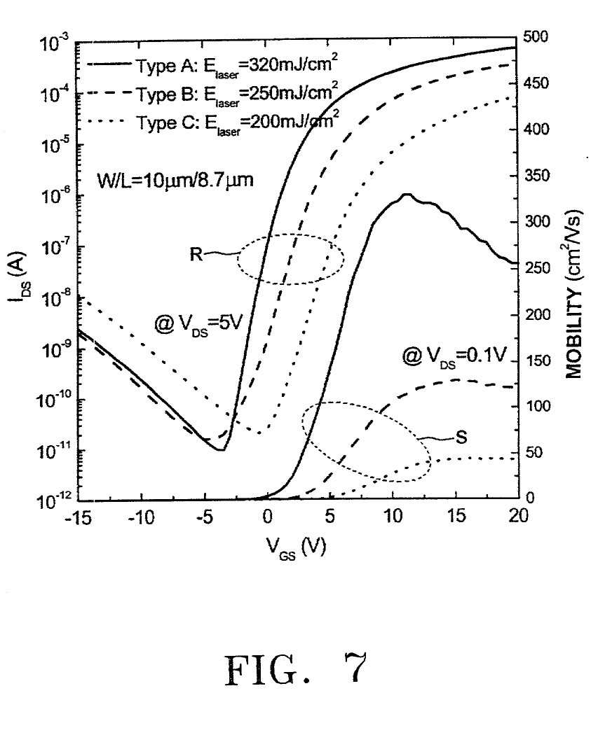

FIG. 6 shows characteristics of current-voltage transmission and field-effect mobility in the poly-Si TFT fabricated by the embodiment of the invention, in which plots included in “P” and referred to “Q” respectively denote the current-voltage transmission characteristic along the drain-to-source voltage VDS and the field-effect mobility in VDS=0.1 V. As shown the graph of FIG. 6, the present poly-Si TFT is operative with a lower leakage current, an advanced slope in the sub-threshold region, and the field-effect mobility of 331 cm²/Vₛ. In FIG. 6, it also refers “W/L” as a ration of gate width and length.

FIG. 7 shows operational characteristic of the present poly-Si TFT comparative to variation of the laser energy density. The plots bound to “R” and “S” denote current-voltage characteristics in V_{DS}=5V and features of the field-effect mobility V_{DS}=0.1 V, respectively, in accordance with variation of the laser energy density Eₗₐₛₑᵣ (Type A: Eₗₐₛₑᵣ=320 mJ/cm², Type B: Eₗₐₛₑᵣ=250 mJ/cm², Type C: Eₗₐₛₑᵣ=200 mJ/cm²). As can be seen from FIG. 7, while both the Types A and B are characterized with lower leakage current because of containing non-defective grains at the drain junction (i.e., around the boundary Bd), the Type C including smaller grains over the regions has a higher rate of leakage current and a lower value of field-effect mobility. The following table summarizes the characteristic factors figured out of the present poly-Si TFT.

TABLE 1

| | Type A | Type B | Type C |
|---|---|---|---|
| Eₗₐₛₑᵣ [mJ/cm²] | 320 | 250 | 200 |
| L_{gram} [μm] | ˜4.6 | ˜2.2 ± 0.3 | ˜0.3 |
| μ_{FE} [cm²/V_{sec}] | 331 | 130 | 45 |
| V_{TH} [V] | 2.2 | 5.3 | 10.2 |
| S [V/dec] | 0.675 | 1.176 | 1.316 |
| I_{L} [A] @ V_{DS} = 5V | 2.3 × 10⁻¹⁰ | 1.7 × 10⁻¹⁰ | 1.3 × 10⁻⁹ |
| V_{GS} = −10 V | | | |

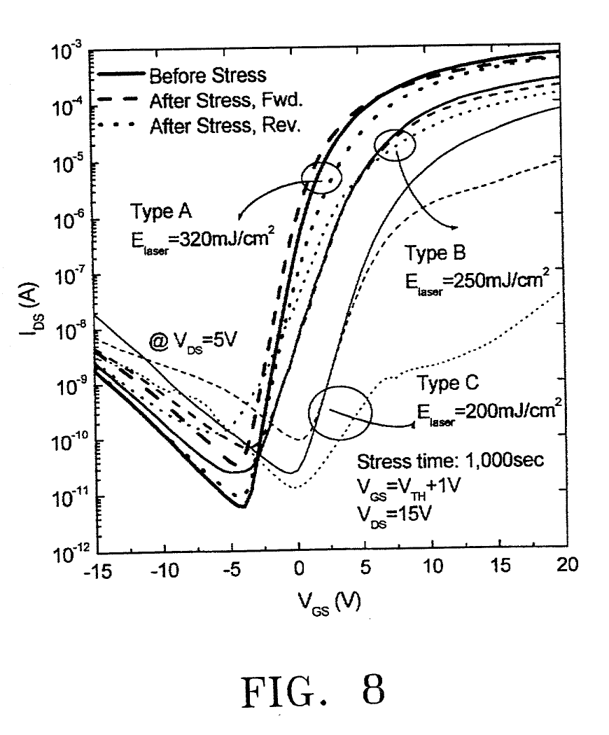

FIG. 8 shows electrical reliabilities in accordance with structures of grains in the present poly-Si TFT, evaluating current-voltage characteristics in V_{DS}=5V in accordance with variation of the laser energy density Eₗₐₛₑᵣ (Type A: Eₗₐₛₑᵣ=320 mJ/cm², Type B: Eₗₐₛₑᵣ=250 mJ/cm², Type C: Eₗₐₛₑᵣ=200 mJ/cm²) after applying a stress bias, which is capable of generating hot carriers, thereto for 1000 seconds. The electrical reliabilities are enhanced in proportion to enlargement of the grain sizes in the Types A and B.

As aforementioned, the poly-Si TFT according to the present invention has an enhanced field-effect mobility, a lower leakage current, and an advanced electrical reliability against stress due to hot carriers, which arises from the grain structure with gain boundaries in the active channel region by forming coarse grains of uniform patterns larger than 4 μm.

Moreover, it is available to simplify a crystallizing procedure for the better grain structure with uniformity by irradiating a laser one time.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A thin-film transistor comprising:
an insulated substrate;
a heat blocking layer, definitively formed on the insulated substrate, for reducing a heat transmission rate along a vertical direction, having a lower thermal conductivity;
a semiconductor layer covering the heat blocking layer, including a source region, a drain region, and a channel region defined on the heat blocking layer;
an insulating layer formed on the semiconductor layer, being defined on the channel region; and
a gate electrode formed on the insulating layer, overlapping the channel region.

2. The thin-film transistor of claim 1, wherein the heat blocking layer is formed of an air.

3. The thin-film transistor of claim 2, wherein the semiconductor layer at the channel region is formed of lateral-grown polycrystalline silicon grains larger than 4 μm.

4. The thin-film transistor of claim 1, further comprising an insulating layer interposed between the heat blocking layer and the semiconductor layer.

5. The thin-film transistor of claim 1, wherein the insulated substrate is one of a glass and a crystal wafer, which contains an insulated buffer layer.

6. A method of fabricating a thin-film transistor, comprising the steps of:
preparing an insulated substrate;
forming a passivation pattern on a predetermined area of the insulated substrate, the passivation pattern creating a step coverage over the predetermined area;
sequentially depositing an insulating layer, an amorphous silicon layer, and a capping layer and selectively etching the capping layer, the amorphous silicon layer, and the insulating layer to form an active pattern;
removing the passivation pattern;
converting the amorphous silicon defined in the channel region into a polycrystalline silicon layer by means of an annealing process;
removing the capping layer;
forming a gate insulation layer and a gate electrode on the polycrystalline silicon layer; and
implanting ions into the source and drain regions with a mask composed of the gate insulation layer and the gate electrode and carrying out an annealing process.

7. The method of claim 6, wherein the passivation pattern is made of a material selectively removable by a wet etching process.

8. The method of claim 7, wherein the passivation layer is made of a metal.

9. The method of claim 8, wherein the passivation layer is made of one of Mo and Al.

10. The method of claim 9, wherein the passivation layer is removed by the wet etching process with an etchant of 16H₃PO₄: 1HNO₃: 1HAC: 2H₂O.

11. The method of claim 6, wherein the polycrystalline silicon layer is generated by irradiating an excimer laser into the amorphous silicon layer.

12. The method of claim 11, wherein the eximer laser is actuated in energy density higher than 250 mj/cm².

13. A method of fabricating a thin-film transistor, comprising the steps of:
preparing an insulated substrate;
forming a heat blocking layer defined on a predetermined area of the insulated substrate, the heat blocking layer reducing a heat transmission rate along a vertical direction and having a lower thermal conductivity;
sequentially depositing an insulating layer, an amorphous silicon layer, and a capping layer and selectively etching the capping layer, the amorphous silicon layer, and the insulating layer to form an active pattern;
converting the amorphous silicon defined in the channel region into a polycrystalline silicon layer by means of an annealing process;
removing the capping layer;
forming a gate insulation layer and a gate electrode on the polycrystalline silicon layer; and
implanting ions into the source and drain regions with a mask composed of the gate insulation layer and the gate electrode and carrying out an annealing process.

14. The method of claim 13, wherein the heat blocking layer is an insulating layer.
